(19) United States
(12) Patent Application Publication
(10) Pub. No.: US 2008/0068807 A1
(43) Pub. Date: Mar. 20, 2008

(54) Heat-dissipating device for back light source for flat panel display

(75) Inventors: Alex Horng, Kaohsiung (TW); Liu Te-Chen, Kaohsiung (TW)

Correspondence Address: BIRCH STEWART KOLASCH & BIRCH, PO BOX 747, FALLS CHURCH, VA, 22040-0747, US

(73) Assignee: Sunonwealth Electric Machine Industry Co., Ltd.

(21) Appl. No.: 11/523,641

(22) Filed: Sep. 20, 2006

(51) Int. Cl. H05K 7/20

(52) U.S. Cl. 361/719

(57) ABSTRACT

A heat-dissipating device for a back light source for a flat panel display includes at least one back light unit, a circuit board, and at least one heat-dissipating board. The back light unit includes a lighting element and a thermally conductive portion connected thereto for absorbing heat generated by the lighting element. The circuit board includes at least one assembling hole and is electrically connected to the back light unit to form a back light module. The heat-dissipating board is mounted to a rear side of the heat-dissipating board. The thermally conductive portion of the back light unit is extended through the assembling hole of the circuit and directly in contact with the rear side of the heat-dissipating board, allowing the heat-dissipating board to absorb and thus dissipate the heat generated by the back light module.

### BACKGROUND OF THE INVENTION

1. Field of the Invention

The present invention relates to a heat-dissipating device and, more particularly, to a heat-dissipating device for a back light source for a flat panel display.

2. Description of Related Art

FIG. 1 illustrates a conventional heat-dissipating device for a back light source for a flat panel display. The device comprises a plurality of back light units 6, a circuit board 7, a support frame 8, and a heat-dissipating board 9. The back light units 6 are mounted to a side of the circuit board 7. The back light units 6 are electrically connected to the circuit board 7 such that the circuit board 7 may control the back light units 6 to provide a back light source. Each back light unit 6 includes a base 61, a lighting element 62, and at least two pole plates 63. The base 61 includes a compartment for receiving and positioning the lighting element 62 and the pole plates 63. The lighting element 62 is a light-emitting diode (LED) to provide sufficient light source. Each pole plate 63 is made of conductive metal, extends through a side of the base 61, and is electrically connected to the lighting element 62.

Still referring to FIG. 1, the circuit board 7 is a soft printed circuit board. Each back light unit 6 is electrically connected to the side of the circuit board 7 via the pole plates 63. The support frame 8 includes a compartment 80 for receiving the back light units 6 and the circuit board 7. The heat-dissipating board 9 is made of metal with excellent thermal conductivity, such as aluminum or copper. The heat-dissipating board 9 is coupled to a side of the support frame 8 in a manner that the circuit board 7 is in intimate contact with the heat-dissipating board 9 via the compartment 80.

When the lighting elements 62 create a back light source to form an image on a flat panel display (not shown), the heat generated by the lighting elements 62 are conducted to the circuit board 7 and then to the heat-dissipating board 9 for absorbing the heat energy. Fins (not labeled) are formed on a side of the heat-dissipating board 9 for enhancing the heat-dissipating efficiency via heat exchange with ambient air. Thus, the heat absorbed can be rapidly released to the environment for the purposes of rapidly lowering the temperature.

However, the heat-dissipating efficiency for the back light units 6 is unsatisfactory, since the heat generated by the back light units 6 are indirectly conducted via the circuit board 7 to the heat-dissipating board 9. Further, the circuit board 7 is a soft printed circuit board that is often made of a material with low thermal conductivity (such as fiber glass). The heat-conducting effect of the circuit board 7 is low, leading to poor heat-dissipating efficiency of the back light units 6.

### OBJECTS OF THE INVENTION

An object of the present invention is to provide a heat-dissipating device for a back light source for a flat panel display with enhanced heat-dissipating efficiency to thereby prolong the life of the flat panel display.

Another object of the present invention is to provide a heat-dissipating device for a back light source for a flat panel display with reliable assembly.

### SUMMARY OF THE INVENTION

A heat-dissipating device for a back light source for a flat panel display in accordance with the present invention comprises at least one back light unit, a circuit board, and at least one heat-dissipating board. The back light unit includes a lighting element and a thermally conductive portion connected thereto for absorbing heat generated by the lighting element. The circuit board includes at least one assembling hole and is electrically connected to the back light unit to form a back light module. The heat-dissipating board is mounted to a rear side of the heat-dissipating board. The thermally conductive portion of the back light unit is extended through the assembling hole of the circuit and directly in contact with the rear side of the heat-dissipating board, allowing the heat-dissipating board to absorb and thus dissipate the heat generated by the back light module.

Since the thermally conductive portion of the back light unit extends through the assembling hole to be directly in intimate contact with the rear side of the heat-dissipating board, the thermally conductive portion with excellent thermal conductivity directly absorbs the waste heat and conducts the heat to the heat-dissipating board. The heat-dissipating efficiency of the back light module is enhanced.

Preferably, the back light unit further includes a base for receiving and positioning the lighting element and the thermally conductive portion.

Preferably, the one back light unit further includes at least two contact/conductive members each having a first end electrically connected to the lighting element and a second end electrically connected to the circuit board, the circuit board controlling lighting of the lighting element to provide a back light source.

Preferably, the thermally conductive portion includes an end protruding out of a bottom of the base and exposed outside and at a level higher than the bottom of the base. A distance between the bottom of the base and the end of the thermally conductive portion is not smaller than a length of the assembling hole of the circuit board.

Preferably, the assembling hole has a diameter greater than that of the thermally conductive portion, allowing the thermally conductive portion to extend through the assembling hole for contacting with the rear side of the heat-dissipating board.

Preferably, the heat-dissipating device further includes a support frame having at least one compartment for receiving the back light module.

The circuit board may be directly formed on the rear side of the heat-dissipating board.

A layer of welding flux may be provided on an engaging side of the thermally conductive portion that is engaged with the heat-dissipating board.

Preferably, the layer of welding flux includes solder paste.

Preferably, the heat-dissipating board includes a plurality of heat-dissipating fins extending vertically on a front side thereof, with a heat-dissipating channel defined between a pair of heat-dissipating fins for guiding air to flow vertically and upwardly for dissipating heat from surfaces of the heat-dissipating fins.

Preferably, the circuit board is a soft printed circuit board or a hard printed circuit board.

Preferably, the lighting element is a light-emitting diode.

Preferably, a plurality of heat-dissipating fans are mounted below the heat-dissipating board for enhancing heat-dissipating efficiency of the heat-dissipating board.

Preferably, the thermally conductive portion is mounted on an end of the lighting element.

Preferably, the thermally conductive portion is made of one of aluminum, copper, gold, and silver.

Other objects, advantages and novel features of this invention will become more apparent from the following detailed description when taken in conjunction with the accompanying drawings.

### BRIEF DESCRIPTION OF THE DRAWINGS

FIG. 1 is an exploded perspective view illustrating a conventional heat-dissipating device for a back light source for a flat panel display;

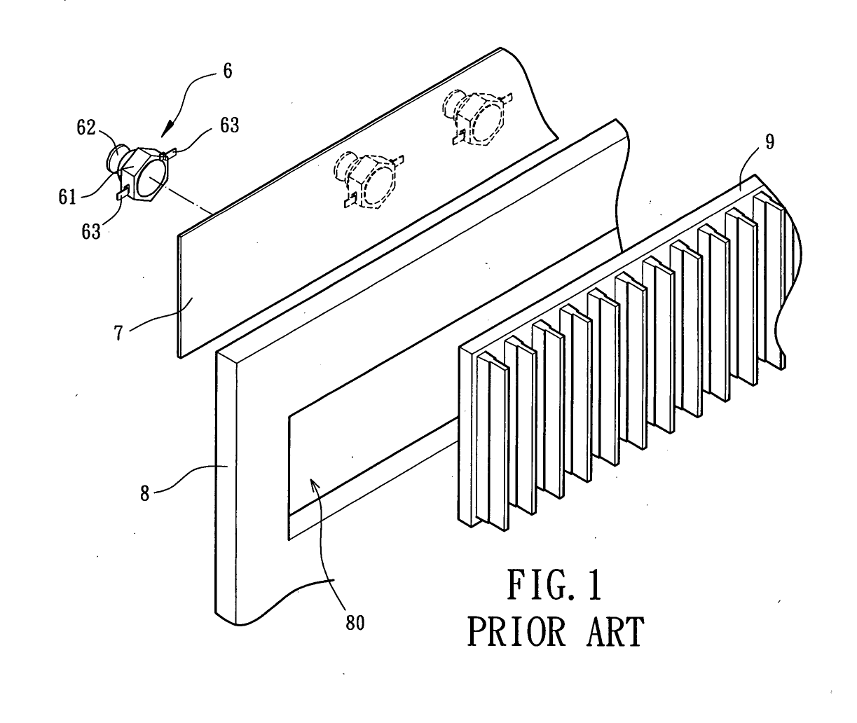

FIG. 2 is an enlarged exploded perspective view illustrating a portion of a first embodiment of a heat-dissipating device for a back light source for a flat panel display in accordance with the present invention;

FIG. 3 is an enlarged sectional view of a portion of the first embodiment of the heat-dissipating device for a back light source for a flat panel display in accordance with the present invention after assembly;

FIG. 4 is an exploded perspective view of the first embodiment of the heat-dissipating device for a back light source for a flat panel display in accordance with the present invention and a flat panel display;

FIG. 5 is an enlarged exploded perspective view illustrating a portion of the first embodiment of the heat-dissipating device for a back light source for a flat panel display in accordance with the present invention and heat-dissipating fans;

FIG. 6 is an enlarged sectional view of a portion of the first embodiment of the heat-dissipating device for a back light source for a flat panel display in accordance with the present invention and the heat-dissipating fan after assembly;

FIG. 7 is an enlarged exploded perspective view illustrating a portion of a second embodiment of the heat-dissipating device for a back light source for a flat panel display in accordance with the present invention; and

FIG. 8 is an enlarged sectional view of a portion of the second embodiment of the heat-dissipating device for a back light source for a flat panel display in accordance with the present invention after assembly.

### DETAILED DESCRIPTION OF THE PREFERRED EMBODIMENTS

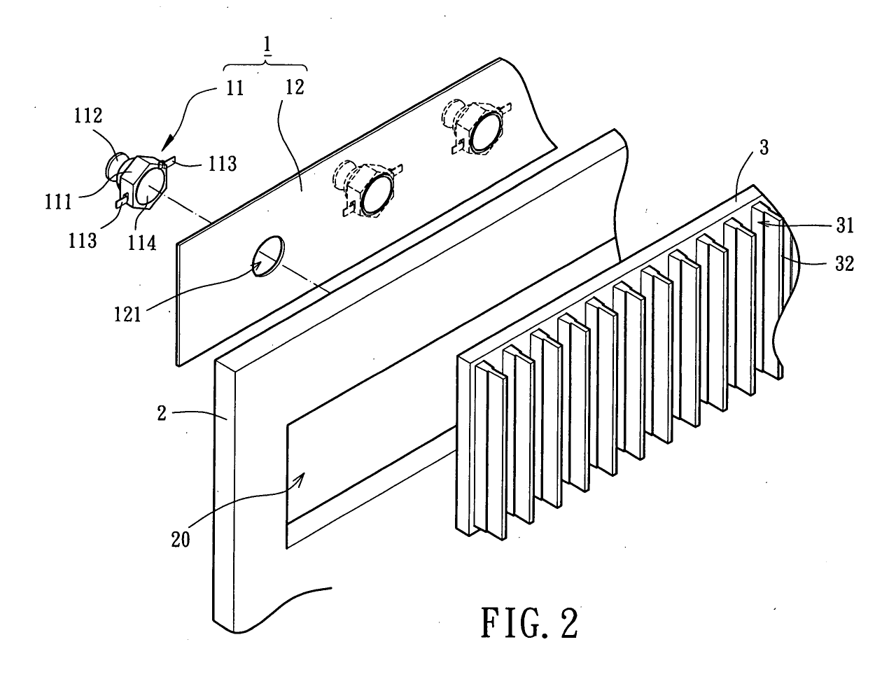

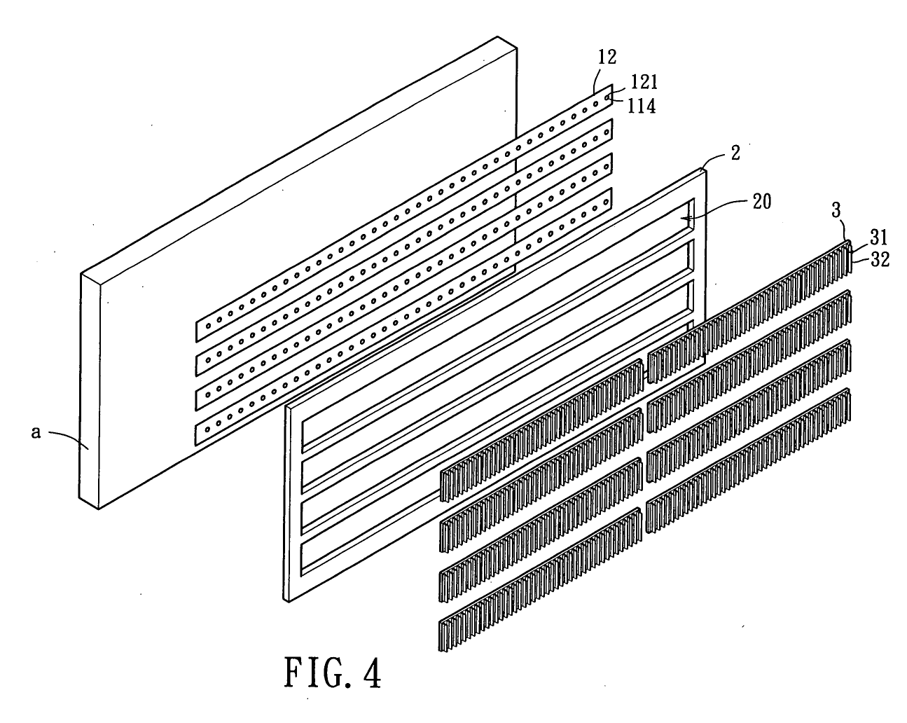

Referring to FIGS. 2 and 4, a first embodiment of a heat-dissipating device for a back light source for a flat panel display in accordance with the present invention is preferably coupled to a rear side of a flat panel display (FPD) “a” that is preferably a liquid crystal display (LCD) or a plasma display panel (PDP). The heat-dissipating device provides back light while proceeding with heat dissipation.

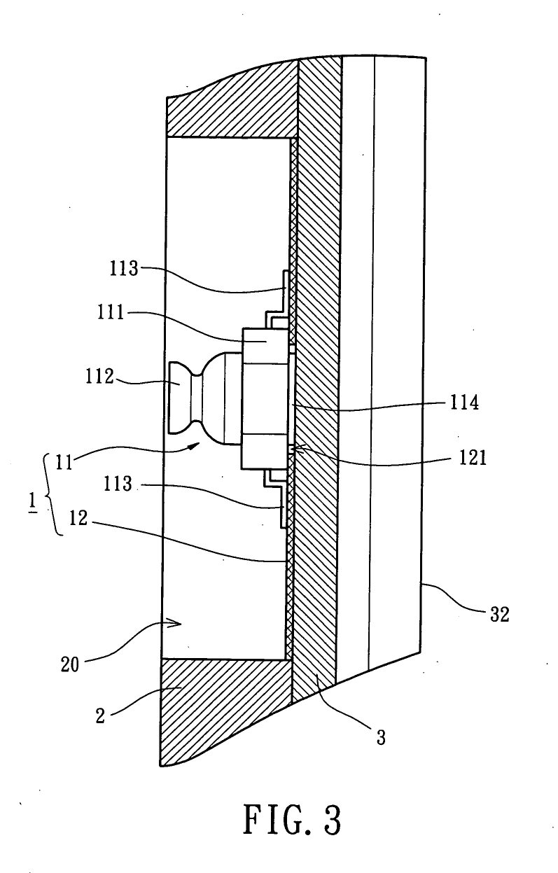

Referring to FIGS. 2 and 3, the first embodiment of the heat-dissipating device for a back light source for a flat panel display in accordance with the present invention comprises at least one back light module 1, a support frame 2, and at least one heat-dissipating board 3. The back light module 1 and the support frame 2 are in intimate contact with a rear side of the heat-dissipating board 3 for carrying out heat dissipation for the flat panel display “a”. The back light module 1 includes at least one back light unit 11 and a circuit board 12 electrically connected to the back light unit 11. The circuit board 12 controls lighting of the back light unit 11 to provide a back light source. Although a soft printed circuit board is preferred, the circuit board 12 may be a hard printed circuit board. The circuit board 12 includes at least one assembling hole 121 through which the back light unit 11 extends to be in contact with the heat-dissipating board 3.

Still referring to FIGS. 2 and 3, the support frame 2 includes at least one compartment 20. The heat-dissipating board 3 is mounted to a side of the support frame 2 whereas the flat panel display “a” is mounted to the other side of the support frame 2. More specifically, the support frame 2 is made of metal or alloy with excellent thermal conductivity, such as aluminum, copper, gold, silver, or alloys thereof. Nevertheless, non-metal material can be used, such as plastic or foam. The compartment 20 is shaped according to the outline of the back light module 1 for receiving the back light module 1 in a manner that the back light module 1 will not protrude outside the support frame 2.

Still referring to FIGS. 2 and 3, the heat-dissipating board 3 is made of metal or alloy with excellent thermal conductivity, such as aluminum, copper, gold, silver, or alloys thereof. A plurality of heat-dissipating fins 32 are provided on a front side of the heat-dissipating board 3 and extend in a vertical direction, with a heat-dissipating channel 31 between a pair of heat-dissipating fins 32. The heat-dissipating fins 32 and the heat-dissipating channels 31 increase the heat-exchange area between the heat-dissipating board 3 and the ambient air, thereby enhancing heat dissipation from the heat-dissipating board 3 to the environment.

Still referring to FIGS. 2 and 3, each back light unit 11 includes a base 111, a lighting element 112, at least two contact/conductive members 113, and a thermally conductive portion 114. A receiving space (not shown) is defined in a center of the base 111 for receiving and positioning the lighting element 112 and the thermally conductive portion 114. The lighting element 112 is preferably a light-emitting diode (LED), more preferably a white light LED. The contact/conductive members 113 are made of metal with excellent electrical conductivity, such as copper, silver, or alloys thereof. Each contact/conductive member 113 extends through a side of the base 111 and has an end electrically connected to the lighting element 112 in the base 111. The other end of each contact/conductive member 113 is electrically connected to the circuit board 12.

The thermally conductive portion 114 is made of metal or alloy with excellent thermal conductivity, such as aluminum, copper, gold, silver, or alloys thereof. The thermally conductive portion 114 may be provided on a bottom of the base 111 and has an end in contact with the lighting element 112. The other end of the thermally conductive portion 114 protrudes out of the base 111 and is thus exposed outside the base 111 and at a level higher than the bottom of the base 111. The distance between the bottom of the base 111 and the other end of the thermally conductive portion 114 is not smaller than a length of the assembling hole 121 of the circuit board 12. A diameter of the assembling hole 121 is greater than that of the thermally conductive portion 114. By such an arrangement, the thermally conductive portion 114 is extended through the assembling hole 121 to be in contact with the rear side of the heat-dissipating board 3.

Still referring to FIGS. 2 through 4, in use, a side of the support frame 2 is mounted to the rear side of the flat panel display “a”. When the lighting elements 112 of the back light units 11 generate waste heat while emitting back light to form an image on the flat panel display “a”. Since the thermally conductive portions 114 of the back light units 11 extend through the respective assembling holes 121 to be directly in intimate contact with the rear side of the heat-dissipating board 3, the thermally conductive portions 114 with excellent thermal conductivity directly absorb the waste heat and conduct the heat to the heat-dissipating board 3. The heat-dissipating efficiency of the back light module 1 is thus enhanced.

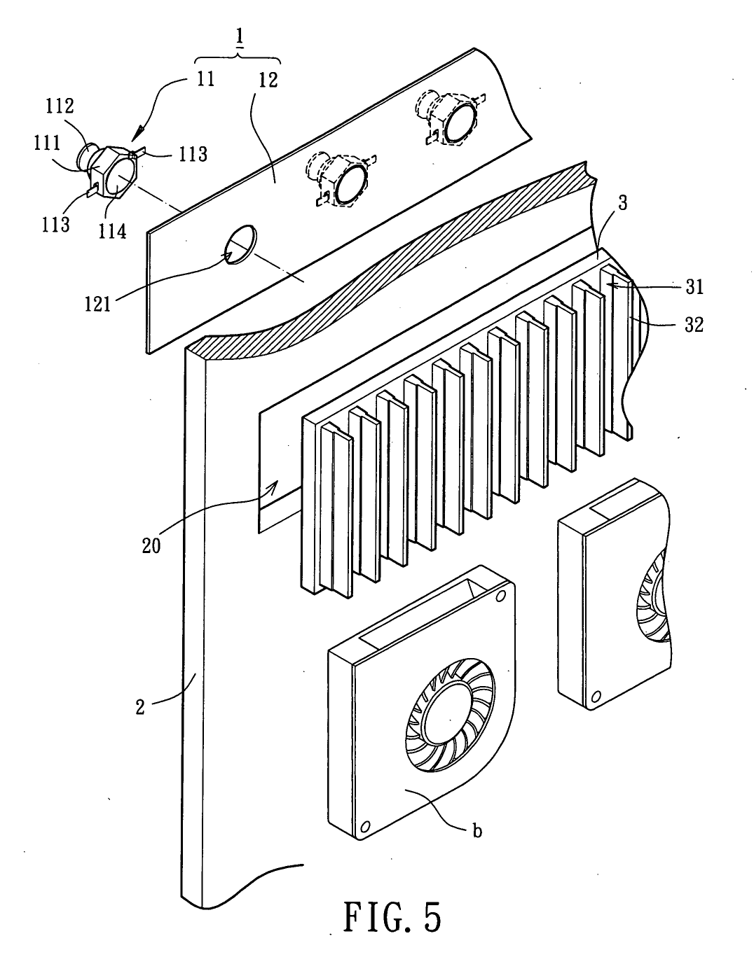

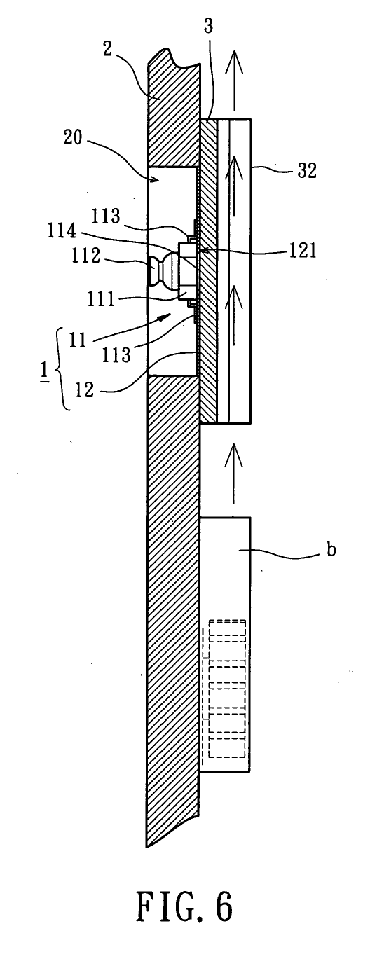

Referring to FIGS. 5 and 6, a plurality of heat-dissipating fans “b” can be provided to enhance the heat-dissipating efficiency. Since the heat-dissipating fins 32 and the heat-dissipating channels 31 extend vertically and since hot air rises, the heat-dissipating fans “b” are preferably located below the heat-dissipating board 3, with the outlets (not labeled) of the heat-dissipating fans “b” aligned with the heat-dissipating channels 31 for speeding up the air in the heat-dissipating channels 31. The heat-dissipating efficiency is thus further enhanced.

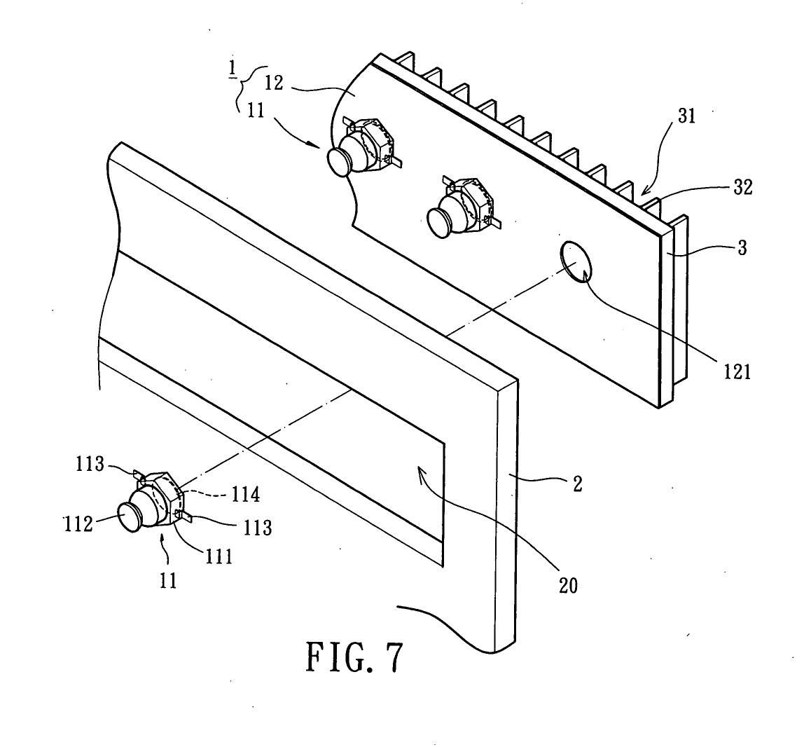

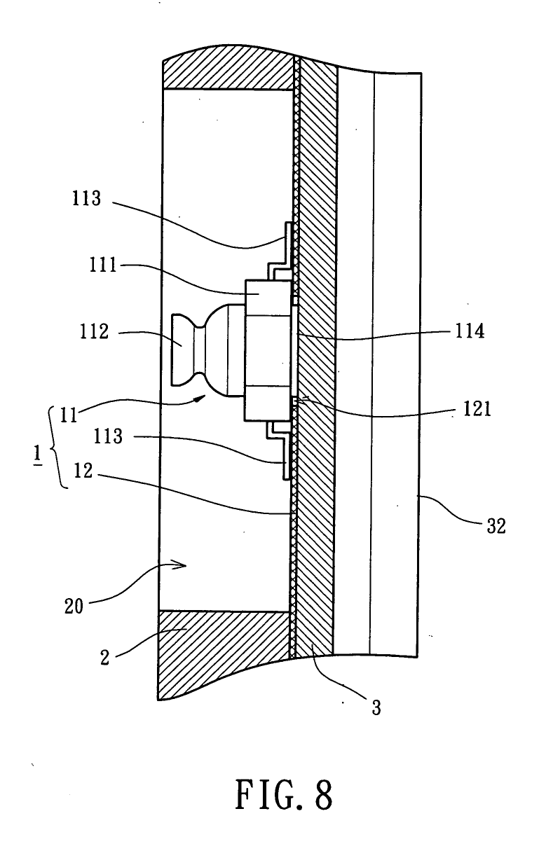

FIGS. 7 and 8 illustrate a second embodiment of the heat-dissipating device for a back light source for a flat panel display in accordance with the present invention. In this embodiment, the circuit board 12 is directly formed on the rear side of the heat-dissipating board 3 and includes at least one assembling hole 121. The thermally conductive portion 114 of the associated back light unit 11 is extended through the assembling hole 121 and in contact with the rear side of the heat-dissipating board 3, thereby effectively enhancing the heat-dissipating efficiency.

In the first embodiment or the second embodiment, when the back light unit 11 is in contact with the rear side of the heat-dissipating board 3 via the assembling hole 121, a layer of welding flux (not shown) can be provided in advance on an engaging side of the thermally conductive portion 114 that is engaged with the heat-dissipating board 3. The layer of welding flux can be heated and molten by surface mount technology (SMT), thereby securely bonding the back light unit 11 to the rear side of the heat-dissipating board 3. The assembling reliability between the light back module 1 and the heat-dissipating board 3 is thus enhanced. The material of the layer of welding flux includes a welding material with excellent thermal conductivity, such as solder paste. The heat-conducting efficiency between the back light module 1 and the heat-dissipating board 3 is further enhanced.

As apparent from the foregoing, the heat-dissipating efficiency of the back light source is effectively enhanced by the heat-dissipating device in accordance with the present invention. The life of the flat panel display is prolonged accordingly.

While the principles of this invention have been disclosed in connection with specific embodiments, it should be understood by those skilled in the art that these descriptions are not intended to limit the scope of the invention, and that any modification and variation without departing the spirit of the invention is intended to be covered by the scope of this invention defined only by the appended claims.

What is claimed is:

1. A heat-dissipating device for a back light source for a flat panel display, comprising:
at least one back light unit including a lighting element and a thermally conductive portion for absorbing heat generated by the lighting element;
a circuit board including at least one assembling hole, the circuit board being electrically connected to said at least one back light unit to form a back light module; and
at least one heat-dissipating board having a rear side mounted to the circuit board, the thermally conductive portion of said at least one back light unit being extended through said at least one assembling hole of the circuit and directly in contact with the rear side of the heat-dissipating board, allowing the heat-dissipating board to absorb and thus dissipate the heat generated by the back light module.

2. The heat-dissipating device as claimed in claim 1, wherein said at least one back light unit further includes a base for receiving and positioning the lighting element and the thermally conductive portion.

3. The heat-dissipating device as claimed in claim 1, wherein said at least one back light unit further includes at least two contact/conductive members each having a first end electrically connected to the lighting element and a second end electrically connected to the circuit board, the circuit board controlling lighting of the lighting element to provide a back light source.

4. The heat-dissipating device as claimed in claim 2, wherein the thermally conductive portion includes an end protruding out of a bottom of the base and exposed outside and at a level higher than the bottom of the base, a distance between the bottom of the base and the end of the thermally conductive portion being not smaller than a length of said at least one assembling hole of the circuit board.

5. The heat-dissipating device as claimed in claim 1, wherein said at least one assembling hole has a diameter greater than that of the thermally conductive portion, allowing the thermally conductive portion to extend through the assembling hole for contacting with the rear side of the heat-dissipating board.

6. The heat-dissipating device as claimed in claim 1 further including a support frame including at least one compartment for receiving the back light module.

7. The heat-dissipating device as claimed in claim 1, wherein the circuit board is directly formed on the rear side of the heat-dissipating board.

8. The heat-dissipating device as claimed in claim 1 further including a layer of welding flux on an engaging side of the thermally conductive portion that is engaged with the heat-dissipating board.

9. The heat-dissipating device as claimed in claim 8, wherein the layer of welding flux includes solder paste.

10. The heat-dissipating device as claimed in claim 1, wherein the heat-dissipating board includes a plurality of heat-dissipating fins extending vertically on a front side thereof, with a heat-dissipating channel defined between any two adjacent heat-dissipating fins for guiding air to flow vertically and upwardly for dissipating heat from surfaces of the heat-dissipating fins.

11. The heat-dissipating device as claimed in claim 1, wherein the circuit board is selected from a soft printed circuit board or a hard printed circuit board.

12. The heat-dissipating device as claimed in claim 1, wherein the lighting element is a light-emitting diode.

13. The heat-dissipating device as claimed in claim 6 further including a plurality of heat-dissipating fans mounted below the heat-dissipating board for enhancing heat-dissipating efficiency of the heat-dissipating board.

14. The heat-dissipating device as claimed in claim 1, wherein the thermally conductive portion is mounted on an end of the lighting element.

15. The heat-dissipating device as claimed in claim 1, wherein the thermally conductive portion is made of one of aluminum, copper, gold, and silver.
